(19) United States
(12) Patent Application Publication
(10) Pub. No.: US 2003/0152175 A1
(43) Pub. Date: Aug. 14, 2003

(54) POST-PROCESSOR USING A NOISE WHITENED MATCHED FILTER FOR A MASS DATA STORAGE DEVICE, OR THE LIKE

(76) Inventors: RYOHEI KUKI, TOKYO (JP); KOSHIRO SAEKI, IRVINE, CA (US)

Correspondence Address: TEXAS INSTRUMENTS INCORPORATED, P O BOX 655474, M/S 3999, DALLAS, TX, 75265

(21) Appl. No.: 09/229,945

(22) Filed: Jan. 13, 1999

(51) Int. Cl. H03D 1/00

(52) U.S. Cl. 375/350

(57) ABSTRACT

A post-processor (10) is added to a PRML read channel in a mass data storage device for improving the error rate performance. The post-processor (10) includes dominant error pattern detection filters, which include a noise-whitening filter (32) and an error pattern matched filter (34). The post-processor improves performance by whitening the colored noise which bring the noise correlation loss, and by generating an error signal when one of the dominant error patterns is detected to enable the data output to be properly corrected.

### BACKGROUND OF THE INVENTION

1. Field of the Invention

This invention relates to improvements in mass data storage devices, or the like, and more particularly to improvements in methods and apparatuses for improving data detection in mass data storage devices of the type that use EPR4 Viterbi data detection techniques.

2. Relevant Background

In the construction of mass data storage devices, or the like, in particular in the construction of the data channel used in digital magnetic recording systems or the like, there has been significant recent interest in Partial Response Maximum-likelihood (PRML) signaling techniques. The most common PRML systems are PR4ML (a partial response class 4) and EPR4ML (extended partial response class 4). Maximum-likelihood detectors, which use a Viterbi algorithm, are generally used for these partial response channels.

In such systems, the use of EPR4 Viterbi data detection techniques is widely used. EPR4 Viterbi detectors are well known, and involve probabilistic techniques for determining data states in the data channel. As data rates increase in the data channel, it becomes increasingly difficult to distinguish adjacent data pulses, and the Viterbi techniques have been found to be very useful.

Unfortunately, significant errors still occur in data detection. For example, using EPR4 techniques, a bit error rate (BER) of about 10⁻⁵ typically occurs. However it has been observed that if the signal to noise ratio in a system could be reduced by, for example, 1 dB, the bit error rate can be improved to 10⁻⁶, representing an order of magnitude improvement. Thus, even small improvements in the signal-to-noise ratio results in large improvements in the bit error rate using EPR4 detection techniques. This is significant since presently the requirements exist for the provision of circuits that have a bit error rate less than 10⁻⁷ , and it is expected that this requirement will continue to become more stringent.

In the past, a typical EPR4 circuit would receive an input signal that has been amplified by a pre-amplifier from the data transducer of the storage device. The amplified signal is applied to an EPR4 equalizer that produces an output that is detected by an EPR4 Viterbi detector. The output from the EPR4 Viterbi detector typically contains the desired data which has been decoded using the above the mentioned probabilistic techniques.

Recently, an EEPR4 channel has been introduced. In comparison to the PR4 partial response target, which is (1−D)*(1+D), and the EPR4 partial response target, which is (1−D)*(1+D)², the EEPR4 partial response target is (1−D)*(1+D)³, where D is a delay operator, equal to e^{jwt}, where w is frequency, and τ is delay time.

As the processing level is increased, however, several problems have emerged. For example, the EPR4ML channel is expected to yield better performance than the PR4ML channel for higher recording densities, but the complexity of the Viterbi detector used in an EPR4ML channel increases by more than twice, and the maximum data rate decreases. In order to avoid these drawbacks, several techniques have been proposed.

One such technique, for example, referred to as a “Turbo-PRML” detection technique, uses a PR4 Viterbi detector followed by a post-processor for EPR4 signals. In such post-processor techniques, PR4 equalized samples are applied to a PR4 Viterbi detector that produces a preliminary estimate of the binary input sequence. Then, preliminary estimate is sensed by the post-processor, which produces a final improved estimate of the binary input sequence, for instance by correcting non-overlapping minimum distance error-events.

Since the post-processor can use the same metric as an EPR4 Viterbi detector, the criteria used to correct minimum distance error-events can be the same criteria as those used in an EPR4 Viterbi detector to select survivor paths. The main benefits to such post-processing approaches is that the feedback path associated with the updating process for the Viterbi detector is limited, allowing for more pipeline and higher channel rates.

FIG. 1 is a block diagram of a post-processor circuit 200 that can be used in conjunction with a mass data storage device, or the like, in accordance with the “Turbo PR4” technique described above. The circuit 200 receives a read back signal as its input on line 201. The signal may be, for example, the output of a pre-amplifier for the signal detected by the head transducer of an associated mass data storage device, or the like. The input line 201 is connected to the input of the PR4 equalizer circuit 214, which produces an output on line 212 to a PR4 Viterbi detector 216, after having been digitized and sampled. The recovered data output from the PR4 Viterbi detector 216 is applied to a post-processor circuit 220, and more particularly to a Viterbi error correction circuit 222, which produces an output on line 224.

The recovered data output from the PR4 Viterbi detector is also applied to a circuit 226, which has a transfer function equal to (1−D)(1+D)², in order to condition the signal to match the actual sampled partial response target signal applied to the input of the Viterbi 216. The output from the circuit 226 is subtracted from the actual sampled partial response target, which has been delayed an amount established by a delay circuit 228 to account for the processing delay introduced by the PR4 Viterbi detector 216.

The subtracted signal represents a PR4 error sample, which is applied to a filter 230, which applies a transfer function (1+D) to the signal. The output from the filter 230 represents a tentative EPR4 error sample, which is connected on line 231 to the input of a dominant error pattern detection filter circuit 232 that detects a dominant error pattern in the signal being processed. The output from the detection filter 232 is applied to the Viterbi error correction circuit 222 to correct the recovered data signal produced at the output of the Viterbi detector 216 in accordance with the particular error pattern detected by the error pattern detection filter 232. As mentioned, the post-processor 220 can improve the performance of a PR4ML channel to that of an EPR4ML channel.

Another technique that has been used is referred to as simplified partial error response detection (SPERD). A SPERD detector considers only two types of error-events ending at each state along the path of the PR4 Viterbi. Since short error-events are more likely than long error-events, this approach considers only the two shortest Euclidean distance error events, which correspond to making one or two symbol errors. One drawback of this approach is that the probabilities of longer error-events increase in modulation codes with looser constraints. The recent progress of semiconductor process technology can easily realize a full EPR4ML channel IC without any turbo technique mentioned above, but the demand of the higher recording densities will require better performance than an EPR4ML channel.

The performance of the EPR4ML channel would be expected to be improved by an additional EEPR4 post-processor that uses a (1+D) filter. But in fact such post-processor using a (1+D) filter and tentative EEPR4 error samples does not actually improve performance, and, moreover, even the performance of an EEPR4 channel is not be improved by a EEEPR4 post-processor which uses a (1+D) filter and tentative EEEPR4 error samples. Thus, as the detection circuitry becomes more complex, for example, in circuitry in which the equalizer and Viterbi are EPR4, or EEPR4, devices, previously used post-processors can not be used.

What is needed, therefore, is a post-processor that can improve the performance of both the EPR4ML and EEPR4ML channels.

### SUMMARY OF THE INVENTION

In light of the above, therefore, it is an object of the invention to provide a post-processor that can improve the performance of both the EPR4ML and EEPR4ML channels of a mass data storage device, or the like, but which can be applied to other target partial response channels as well.

Thus, according to a broad aspect of the invention, a sampled data detection technique is presented for use in a mass data storage device. The technique includes equalizing and sampling a read back signal from a transducer head of the mass data storage device to a partial response level of at least EPR4 to produce an actual sampled partial response target signal. The actual sampled partial response target signal is detected in a Viterbi detector, which having a partial response detection level of at least EPR4 to produce a recovered data output signal. The actual sampled partial response target signal is delayed for a time substantially equal to a time required by the Viterbi detector to generate the recovered data output signal from the actual sampled partial response target signal to produce a delayed actual sampled partial response target signal. The recovered data output signal is converted to a partial response level of the actual sampled data output signal to produce a converted recovered partial response target signal. The converted recovered partial response target signal is subtracted from the delayed actual sampled partial response target signal to produce an error signal. The occurrence of a predetermined error event pattern is determined in the recovered data output signal to produce an error event pattern indicating signal from which a detection signal is produced having a magnitude based upon the occurrence of an error event. The detection signal is compared to a predetermined threshold level, and an error correction control signal is generated if the data detection signal is larger than the predetermined threshold level, and the error event pattern-indicating signal indicates an occurrence of an error pattern. Finally the recovered data output signal is corrected to correspond to the predetermined data pattern if the error correction control signal has been generated.

The equalizing may include equalizing the read back signal to a partial response level of EPR4 or to EEPR4, and the detecting may include detecting the actual sampled partial response target signal in a Viterbi detector having a partial response detection level of EPR4 or EEPR4.

Determining the occurrence of a predetermined error event pattern in the recovered data output signal comprises determining the occurrence of an error pattern of ex=±{1}, ex=±{1-11}, ex={1-1}, or other data sequence having a high likelihood of occurrence in the recovered data output signal.

According to another broad aspect of the invention, a post-processor circuit is presented for use in a sampled data read channel of a mass data storage device. The post-processor includes a Viterbi detector that receives an actual sampled partial response target signal from a storage medium of the mass data storage device to produce a recovered data output signal. An error pattern detector generates an error pattern event-indicating signal if a predetermined error event pattern occurs in the sampled partial response target signal. A circuit is provided for generating an error signal based upon a difference between the recovered data output signal and a delayed the actual sampled partial response target signal. A threshold circuit generates an error correction control signal if a magnitude of the absolute value of the filtered error signal exceeds a predetermined threshold, and an error correction circuit modifies the recovered data output signal when the error correction control signal and the error event pattern indicating occurrence signal are generated.

### BRIEF DESCRIPTION OF THE DRAWING

The invention is illustrated in the accompanying drawings, in which:

FIG. 1 is a block diagram of a post-processor circuit that can be used in conjunction with a mass data storage device, or the like, in accordance with the prior art.

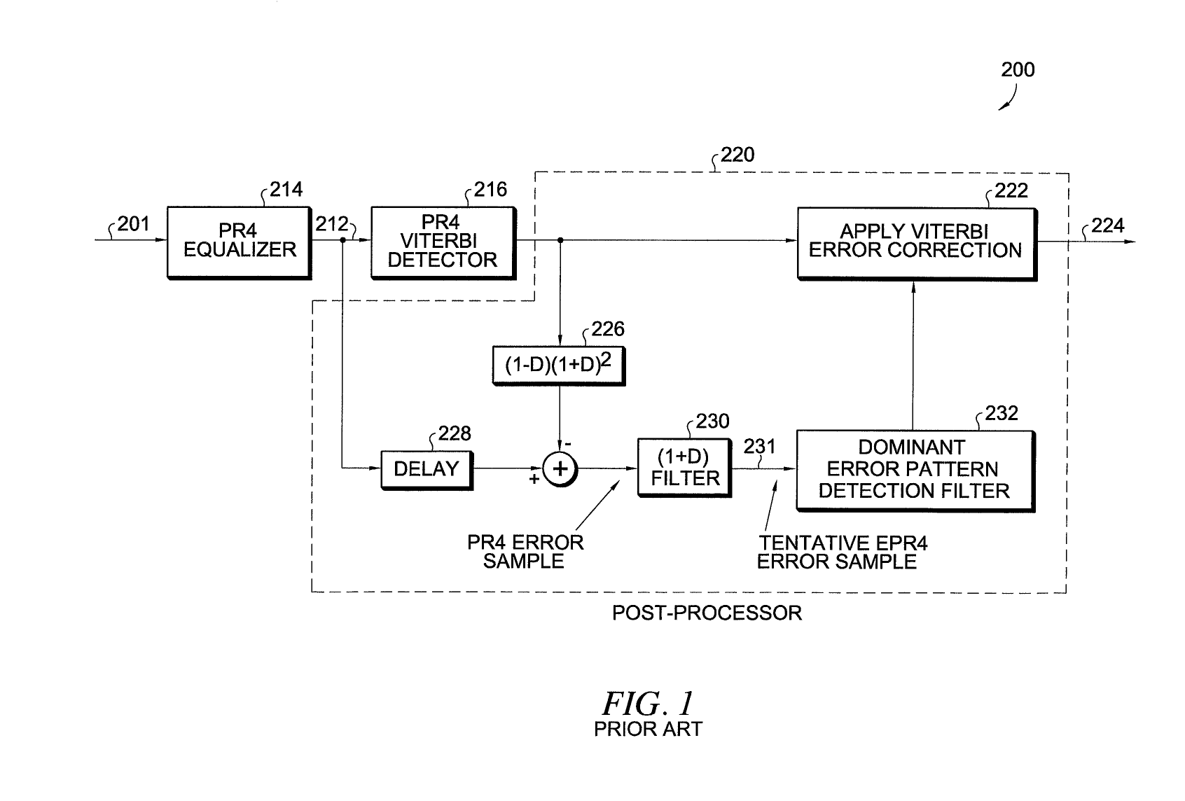

FIG. 2 is a block diagram of a 16/17 EPR4 detector, which includes a post-processor circuit that can be used in conjunction with a mass data storage device, or the like, in accordance with a preferred embodiment of the invention.

FIG. 3 is a block diagram of a dominant error pattern detector, which may be used in the detector of FIG. 2, in accordance with a preferred embodiment of the invention.

FIG. 4 is a block diagram of a portion of a channel of a mass data storage device, or the like, representing a 16/17 code EPR4 channel through which data can be written to and read from a data media, in accordance with a preferred embodiment of the invention.

FIG. 5 is a box diagram showing an error pattern validation algorithm that can be used to minimize false detection by deciding whether or not an error correction should be made in processed data at an output of a PR4 Viterbi detector, in accordance with a preferred embodiment of the invention.

FIG. 6 is a block diagram error detection filter for a data error pattern of ex=±{1-11}, in accordance with a preferred embodiment of the invention, which may be used in the circuit of FIG. 2.

FIG. 7 is a block diagram error detection filter for a data error pattern of ex=±{1}, in accordance with a preferred embodiment of the invention, which may be used in the circuit of FIG. 2.

FIG. 8 shows a graph of a computer simulation comparing the bit error rate performance with and without the post-processor for an EPR4ML channel, in accordance with a preferred embodiment of the invention.

And FIG. 9 is the optimized error pattern detection filters for data error patterns of ex=±{1-1} in a Trellis 8/9 code EEPR4 channel, in accordance with a preferred embodiment of the invention.

### DETAILED DESCRIPTION OF THE PREFERRED EMBODIMENTS

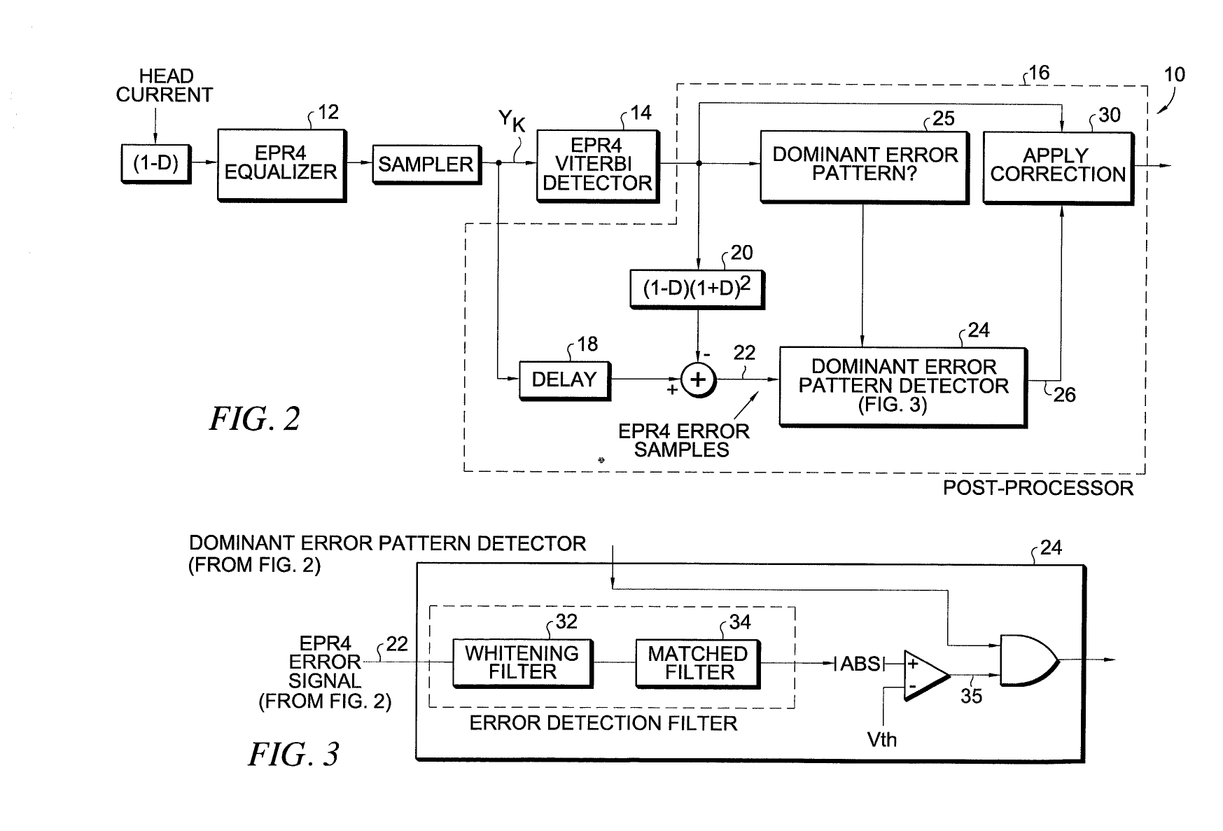

A portion of a read channel of a mass data storage device, which includes a 16/17 EPR4 detector, according to a preferred embodiment the invention, is shown in FIG. 2. The detector can be used to determine and correct error patterns in signals that have been equalized by an EPR4 equalizer 12 and detected by an EPR4 Viterbi detector 14, using a post-processing circuit 16. The post-processing circuit 16 receives the recovered data output signal from the EPR4 Viterbi detector 14 and processes it to determine whether an error has occurred with respect to the two data error patterns that are statically most likely to occur, namely ex=±{1} and ex=±{1-11}.

To make this error pattern determination and correction, the output signal from the EPR4 equalizer 12 is digitized, sampled, and applied to a delay circuit 18 to produce a delayed actual sampled partial response target signal from which the recovered data output from the Viterbi detector 14 is subtracted, after having been modified by a circuit having a transfer function of (1−D) (1+D)². The difference signal on line 22 represents an error signal, which provides an input to a circuit 24 that detects the presence of dominant error patterns.

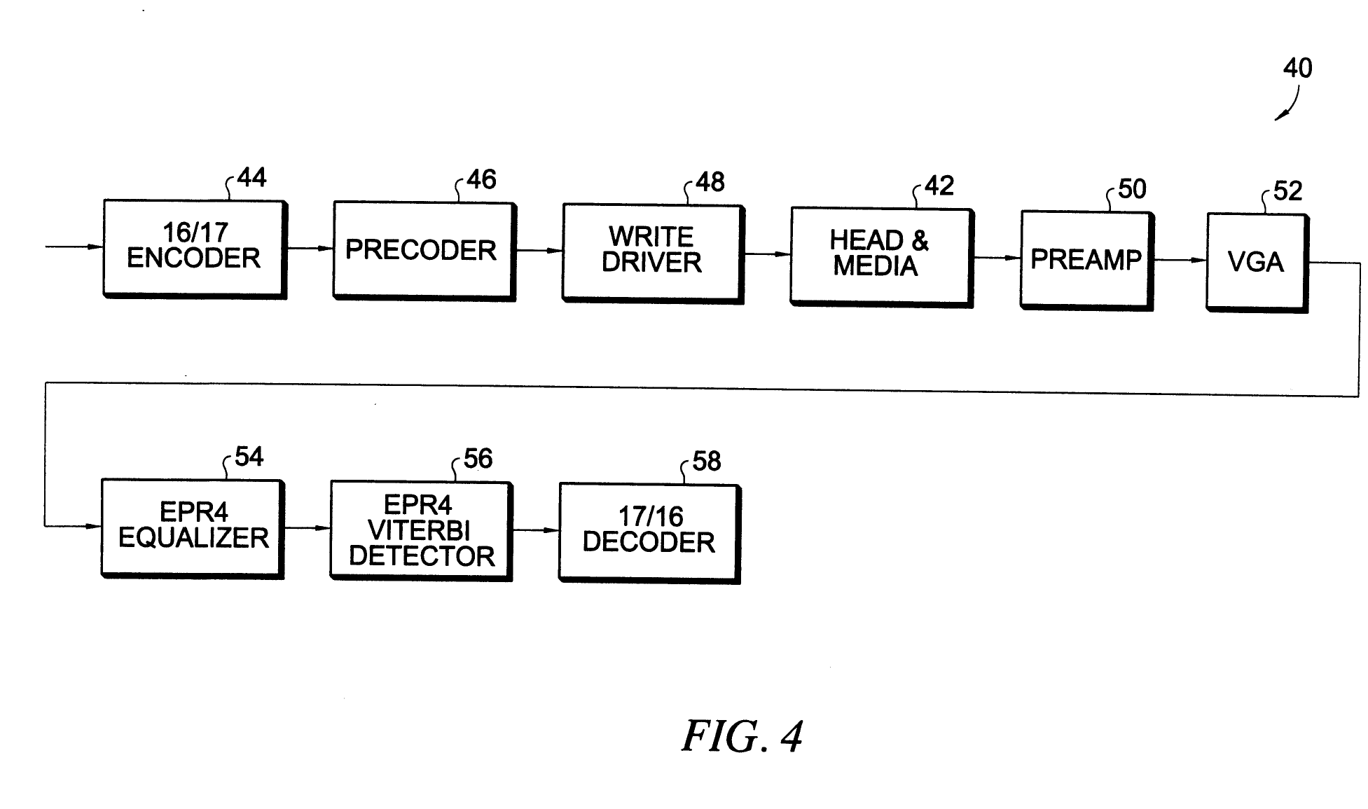

Details of the dominant error pattern detector circuit 24 are described below with respect to FIG. 3. The circuit 24 determines whether one of the dominant error patterns has been miss-detected through threshold-determining techniques described below in detail. When the error pattern detector circuit 24 determines that an error has occurred in the detection of a dominant data pattern, an output is produced on output line 26 to a circuit 30 which applies a correction to the data pattern.

More particularly, the input to the EPR4 Viterbi detector 14 represents the actual sampled value of the EPR4 target. The actual sampled value, of course, includes noise. A perfect signal with no noise present would be represented by (1−D) (1+D)². Consequently, since the output signal from the EPR4 Viterbi detector 14 represents the recovered write current, in order for it to be properly processed, the signal needs to be converted to an EPR4 target signal. Consequently, the transfer function of the block 20 is provided as (1−D) (1+D)².

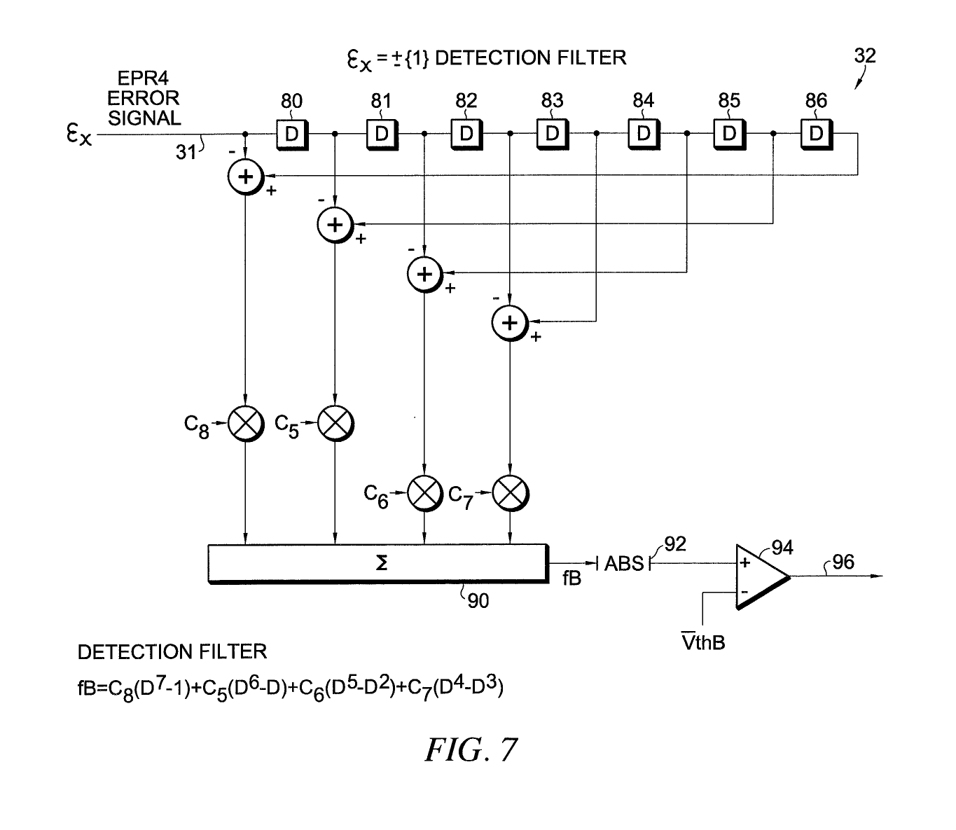

The dominant error pattern detector 24 of FIG. 3 includes a whitening filter 32 followed by an FIR or a matched filter 34. The matched filter 34 may take different forms, depending upon the particular dominant error pattern to be detected. Various circuits that may perform the whitening filter and matched filter function (i.e., the error detection function, are shown in described below with respect to FIGS. 6, 7, and 9. In operation, when the error signal applied to the error detection circuit increases, the signal produced at the output increases. The absolute value of the output is compared to a predetermined threshold, and if it exceeds the threshold, will produce a state change to an AND gate. At the same time, if the occurrence of a dominant error pattern is detected by a dominant error pattern detector 25, which controls the AND gate of the dominant error pattern detector 24, an output is generated to direct the apply correction circuit 30 to correct the error in the recovered data output from the Viterbi detector 14.

Thus, to summarize the action of the circuit 10, the circuit 10 continually monitors the actual sampled partial response target signal to determine the presence of known error patterns, for example, the two most frequently occurring or dominant error patterns, ex=±{1} and ex=±{1-11}, with an EPR4 Viterbi detector. Concurrently, the circuit determines an error value on line 35 indicative of the selected dominant error patterns. If the error value on line 35 exceeds a predetermined threshold, the data pattern is corrected.

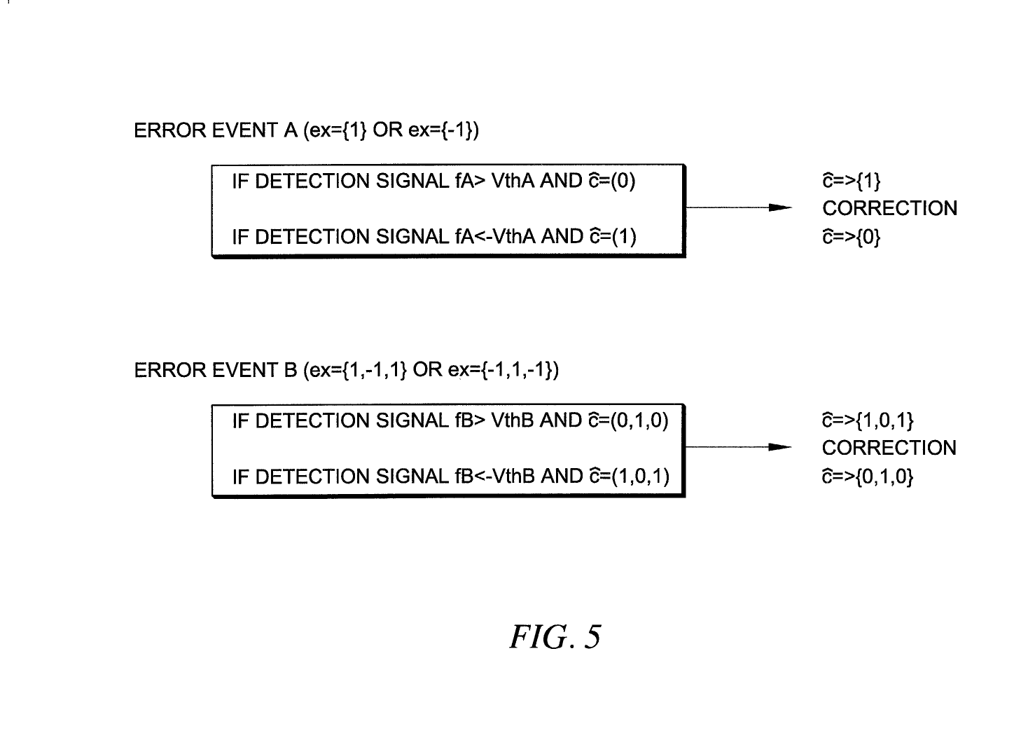

FIG. 4 is a diagram of a circuit 40 representing a 16/17 code EPR4 channel model. The circuit 40 is intended to write data to or read data from the data medium of a mass data storage device (not shown). To this end, a data media and head transducer are provided, in known manner, as shown in block 42. To write data to the media, the data is first encoded, block 44, for example, with a 16/17 encoding pattern. After encoding, the signal is coded in a pre-code circuit 46 and applied to the head transducer and media 42 by a write driver 48.

On the other hand, to read data previously written to the media of the mass data storage device, the data in its raw form is read from the data media by the head transducer 42 and amplified by a pre-amplifier circuit 50. Typically, the amplitude of the pre-amplified signal is adjusted by a variable gain amplifier (VGA) 52, equalized in an EPR4 equalizer 54, and detected in an EPR4 Viterbi detector 56. A 17/16 decoder 58 then decodes the output from the Viterbi detector 56.

The dominant error patterns of 16/17 code EPR4 channel are shown in Table 1. This table was calculated by assuming that the signal is a Loretzian pulse, the noise is AWGN (Additive White Gaussian Noise), and the equalizer is an ideal filter, which has no equalizer error.

TABLE 1

| Error | Du = 2.0 | | | Du = 2.75 | | |
|---|---|---|---|---|---|---|
| Patterns | BER | | | BER | | |
| ex | 10⁻⁵ | 10⁻⁷ | 10⁻⁹ | 10⁻⁵ | 10⁻⁷ | 10⁻⁹ |
| ±{1} | 75.15% | 77.98% | 79.48% | 8.85% | 1.83% | .34% |
| ±{101} | .61 | .12 | .02 | .00 | .00 | .00 |
| ±{10101} | .48 | .04 | .02 | .00 | .00 | .00 |
| ±{1010101} | .20 | .02 | .01 | .00 | .00 | .00 |
| ±{1-11} | 16.81 | 16.67 | 16.22 | 87.47 | 97.12 | 99.35 |
| ±{1-11-11} | 2.70 | 2.30 | 1.91 | .94 | .26 | .06 |
| ±{1-11-11-11} | .52 | .51 | .50 | .37 | .16 | .07 |
| ±{1-11-1} | .93 | .37 | .14 | .96 | .19 | .03 |
| ±{1-11-11-1} | 1.65 | 1.61 | 1.54 | .94 | .38 | .14 |
| ±{1-11-11-11-1} | .13 | .12 | .12 | .09 | .04 | .02 |
| ±{1-1} | .69 | .14 | .03 | .37 | .02 | .00 |

“Du” means user density which is defined by PW50/Td, where PW50 is the pulse width at the 50% amplitude point of the channel step response and Td is the duration of the user data bit. The error pattern “ex” is the difference between a correct bit and an error bit at the channel input. “1” means “0” B>“1” error, and “0” means “1” C>“0” error. “0” means no error.

An error pattern “ex” is converted to a 16/17-code error pattern. The converted 16/17 code error patterns of ex=±{1} and ex=±{1-11} are shown in Table 2.

TABLE 2
ex = ±{1}

| 0 | | 1 | 0 | | 1 |
|---|---|---|---|---|---|
| 000 | ← → | 101 | 011 | ← → | 100 |
| 010 | ← → | 111 | 011 | ← → | 110 |

ex = ±{1-11}

| | | | | | |
|---|---|---|---|---|---|
| 01000 | ← → | 10011 | 00000 | ← → | 11011 |
| 01010 | ← → | 10001 | 00010 | ← → | 11001 |
| 01001 | ← → | 10010 | 00001 | ← → | 11010 |
| 01011 | ← → | 10000 | 00011 | ← → | 11000 |

The probability of appearance of the error pattern depends on the “Du” and the BER (bit error rate) in code bits. It can be seen from Table I that the two dominant error patterns (“ex”=±{1} and “ex”=±{1-11}) occupy more than 90% of all error patterns. Thus, if a post-processor can remove these two dominant error patterns, the BER will be better by more than one order of magnitude.

As indicated above, a post-processor which processes tentative EEPR4 error samples with a (1+D) filter cannot remove most of “ex”=±{1-11} error patterns, therefore a performance improvement using this type of filter cannot be expected. The post-processor, therefore, must have better performance than the Viterbi detector for these designated two dominant error patterns.

One of the main reasons that the “ex”=±{1} errors and the “ex”={1-11} errors are dominant is that the noise of these two patterns is enhanced by the correlation of colored noise in the channel. More particularly, the input noise to the read channel is mainly electronic noise and media noise. The electronic noise is white noise that has constant power in the frequency domain, and does not have any correlation. On the other hand, the media noise is colored noise whose spectrum is not constant, and has correlation. Even if the input noise to read channel is 100% white noise, the equalizer filter colors the noise, which results in the noise having at least some correlation. In fact, the correlated noise often degrades the BER performance of the Viterbi detector (noise correlation loss). The noise correlation loss depends on the error pattern and “Du”. The calculated noise correlation loss of an EPR4 Viterbi is shown in Table 3.

TABLE 3

| Error Pattern | Du = 2.00 | Du −2.75 |
|---|---|---|
| Ex = ±{1} | 1.675 dB | 1.110 dB |
| Ex = ±{1-11}) | 1.630 dB | 2.532 dB |

Thus, this invention offers a method to implement a post-processor that reduces the noise correlation loss and improves the BER performance. The error pattern detection filter 24 of this invention therefore includes a noise-whitening filter 32 and an error pattern matched filter 34. The noise-whitening filter 32 whitens the noise colored by the equalizer, and the error pattern matched filter 34 is a maximum-likelihood detector for the output signals of the noise whitening filter 32.

The transfer function of the noise-whitening filter 32 is:

NW(D)=(1+a1*D+a2*D²+ . . . +an*Dⁿ)/(1+b1*D+b2*D²+ . . . +bm*D^{m})

where a1, a2, . . . , an and b1, b2, . . . , bm are coefficients that depend upon the recording densities of the data on the media of the mass data storage device. Although the noise is not completely whitened by this filter, by optimizing the above coefficients the whitening filter can remarkably reduce any noise correlation loss, and can improve the BER performance.

Thus, to analyze the circuit 10, the transfer function of the “ex”=±{1-11} data pattern is EX(D)=±(1−D+D²).

The transfer function of the ex=±{1} data pattern is EX(D)=±(1).

The transfer function of the EPR4 channel is EPR(D)=(1−D)*(1+D)².

The overall transfer function of the output of the noise-whitening filter is EY(D)=EX(D)*EPR(D)*NW(D).

The matched filter of the error pattern “ex”={1-11} is derived by replacing D of EY(D) to D⁻¹.

MF(D)=EY(D⁻¹)=EX(D⁻¹)*EPR(D⁻¹)*NW(D⁻¹).

The matched filter MF(D) is a maximum likelihood detector of the error pattern ex=±{1-11}.

The transfer function of the error pattern ex=±{1-11} detection filter of the post-processor is DF(D)=NW(D)*MF(D).

For simplicity, the noise-whitening filter can be analyzed using the following transfer function.

NW(D)=(1+a1*D+a2*D²+a3*D³)/(1+D)

The error pattern ex=±{1-11} detection filter is

DF1(D)=±(1+a1*D+a2*D²+a3*D³)/(1+D)*(1−D⁻¹+D−2*(1−D⁻¹)*(1+D⁻¹)²*(1+a1*D⁻¹+a2*D⁻²+a3*D⁻³)/(1+D^{31 1})=±(c0*(D³−1)+c1*(D³−D)+c2*(D⁷−D²) +c3*(D ⁶−D³)−c

where c0=a3,

c1=a2−2*a3+a1*a3,

c2=a1−2*a2+a1*a2+2*a3−2*a1*a3+a2*a3,

c3=1−2*a1+2*a2−a3−2*a1*a2+2*a1*a3−2*a2*a3+a1²+a2²+a3²

c4=2−3*a1+a2−3*a1*a2+a1*a3−3*a2*a3+2*a1²+2*a2²+2*a3²

Using a similar method, the error pattern an “ex”=±{1} detection filter is:

DF2(D)=±(c8*(D⁷−1)+c5*(D⁶−D)+c6*(D⁵⁻D²)+c7*(D⁴−D⁵))

The optimization of the coefficients of the error pattern detection filters is done by maximizing the SNR of the output of the error pattern detection filters by computer techniques. The signal of the error pattern detection filter is equal to the squared Euclidean distance of the EY(D).

For “ex”=±{1-11}, S{1-11}=2*(c2+c4).

For “ex”=±{1}, S(1)=2*(c6+c7).

The optimum detection threshold voltage of the error pattern detection filter is a half of S{1-11} and S{1}.

Therefore, VₜₕA=c2+c4 for “ex”=±{1-11}.

And VₜₕB=c6+c7 for “ex”=±{1}.

If the output signals of the error pattern detection filters are larger than VₜₕA or VₜₕB, the error pattern detection filter detects the Viterbi detector error of the error pattern.

The noise spectrum of the output of the error pattern detection filter is:

N(w)=N0*EQ(D)*DF(D).

Or N(w)=N0*EQ(D)*DF2(D).

Where EQ(D) is the transfer function of EPR4 equalizer filter, and N0 is noise spectrum of the channel input. (N0 is constant for AWGN.)

If the ideal equalizer filter and Loretzian pulse is assumed,

EQ(D)=2/π/k*e^{(w*Ts*k/2)}*(1+D)².

Where Ts is a sampling time(equal to 16/17*Td) and K=PW50/Ts=17/16*Du.

The noise power of the output of the error pattern detection filter is:

$$N = \frac{1}{{2}^{*} π} {\int }_{0}^{\frac{π}{2}} \vert N ( w ) {\vert}^{2} ⅆ w$$

The optimum coefficients (c0-c8) and the detection threshold VₜₕA and VₜₕB) of the error pattern detection filters that maximize the signal to noise ratio can be obtained from the above equations, for example, by computer optimization techniques. (It should be noted that the optimum values of the coefficients and the thresholds depend on the user density, Du, because EQ(D) depends on Du.) The error detection filters sometimes have false detection. In order to minimize any such false detection, the validation logic can be employed to decide whether the correction should be done.

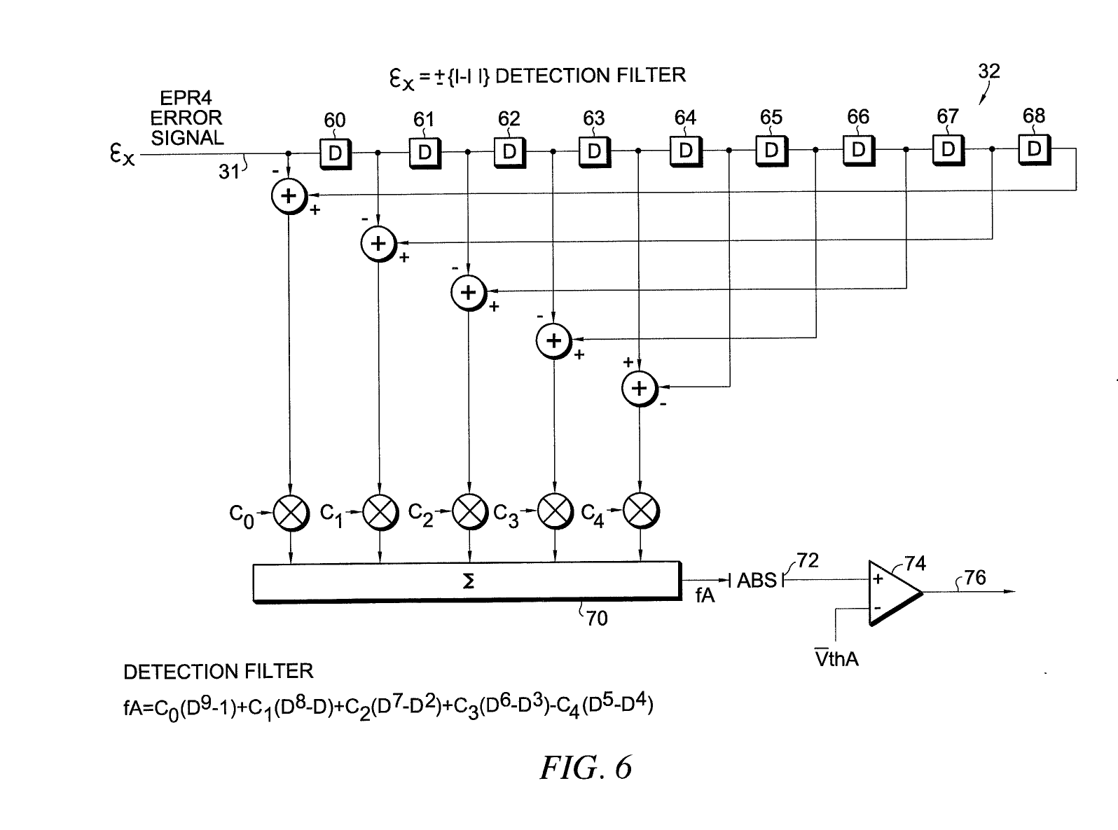

FIG. 5 is the error pattern validation algorithm. The precise form of the error pattern validation algorithm depends upon the particular error event that is to be detected and corrected. Thus, for example, for an error event A in which “ex”={1} or “ex”={−1} is to be verified, if the detection signal fA is >VₜₕA and Ĉ={0}, a correction should be applied. Additionally, if the detection signal fA is <−VₜₕA and Ĉ={1}, a correction also should be applied.

On the other hand, if the error event is one in which the signal “ex”={1,−1,1} or “ex”={−1,1,−1} is to be validated, if the detection signal fB is >VₜₕB and Ĉ={0,1,0}, then a correction occurs. Alternatively, if the detection signal fB is <−VₜₕB, and Ĉ={1,0,1}, then the correction the is applied.

It is difficult to avoid incorrect correction completely, and if the value of Vₜₕ is slightly increased, the probability of the wrong correction decreases; however, the undetected probability of the Viterbi detector error increases. Computer simulations can obtain the optimum threshold values that minimize the bit error rate of the overall channel.

One embodiment for a dominant error pattern detection filter 32, which can be used to provide the dominant error pattern of “ex”=±{1-11}, described above with respect to FIGS. 2 and 3, is shown in FIG. 6. The detection filter 32 includes 9 delay elements 60-68, each delaying the error signal on error signal input line 31 by one delay unit, D, described above. Outputs from respective delay elements 64-68 are respectively summed with the output from delay blocks 63-60 and the signal on the input line 31. It is noted that in the output of delay block 64 is subtracted from the output of delay block 63, whereas the input signal on line 31 and the outputs from the respective blocks 60-62 are subtracted from the outputs of respective delay blocks 68-65.

The difference signals are weighted by respective weights c0, c1, c2, c3, and c4, and the weighted signals summed by a summer circuit 70. The output from the summer circuit 70 is a function fA expressed by fA=C₀(D⁹−1)+C₁(D⁸−D)+C₂(D⁷−D²)+C₃(D⁶−D³)−C₄(D⁵−D⁴). The absolute value of the detection filter output function is taken by absolute value circuit 72 to produce an input to a comparator 74. The magnitude of the input to the comparator 74 is compared to a threshold voltage, VₜₕA, to produce an output on line 76 from the detector filter circuit 32.

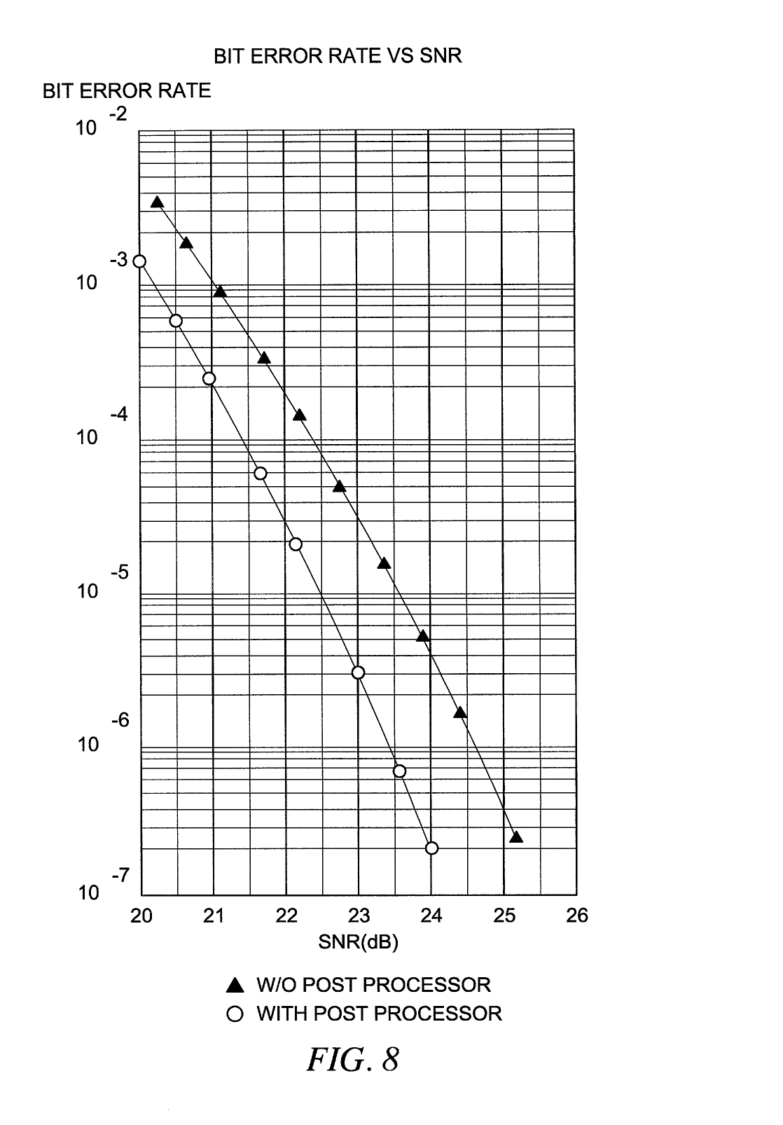

One embodiment for a dominant error pattern detection filter 32 which can be used to detect the “ex”=±{1-1}, which can be used to provide dominant error pattern detection in the circuit of FIGS. 2 and 3, is shown in FIG. 7. The detection filter 32 includes seven delay elements 80-86, each delaying the error signal on error signal input line 31 by one delay unit, D, described above. The signals on the input lines and respective delay elements 80-82 are respectively subtracted from the outputs from respective delay blocks 86-83.

The difference signals are weighted by respective weights c8, c5, c6, and c7, and the weighted signals are summed by a summer circuit 90. The output from the summer circuit 90 is a function fB, which equals C₈(D⁷−1)+C₅(D⁶−D)+C₆(D⁵−D²)+C₇(D⁷−D³). The absolute value of the function fB is produced by absolute value circuit 92 to produce an input to a comparator 94. The magnitude of the input to the comparator 94 is compared to a threshold voltage VₜₕB to produce an output on line 96 from the detector filter circuit 32.

Thus, using either, or both, of the circuits 32 of FIGS. 6 and 7, the post-processor has the selectable two coefficients set. Table 5 is the two sets of coefficients, optimized by computer simulation. The one is for low user density and the other is for high user density.

TABLE 5

| | Event B detector | | | | | Event A Detector | | | |
|---|---|---|---|---|---|---|---|---|---|
| | C0 | C1 | C2 | C3 | C4 | C5 | C6 | C7 | C8 |
| Low User Density (2.0 -2.5) | 0.25 | 0.75 | 0.50 | 1.00 | 1.50 | 0.50 | 1.00 | 1.00 | 0.25 |
| High User Density (2.5-3.0) | 0.50 | 1.00 | 1.00 | 1.00 | 1.00 | 0.50 | 1.00 | 1.00 | 0.25 |

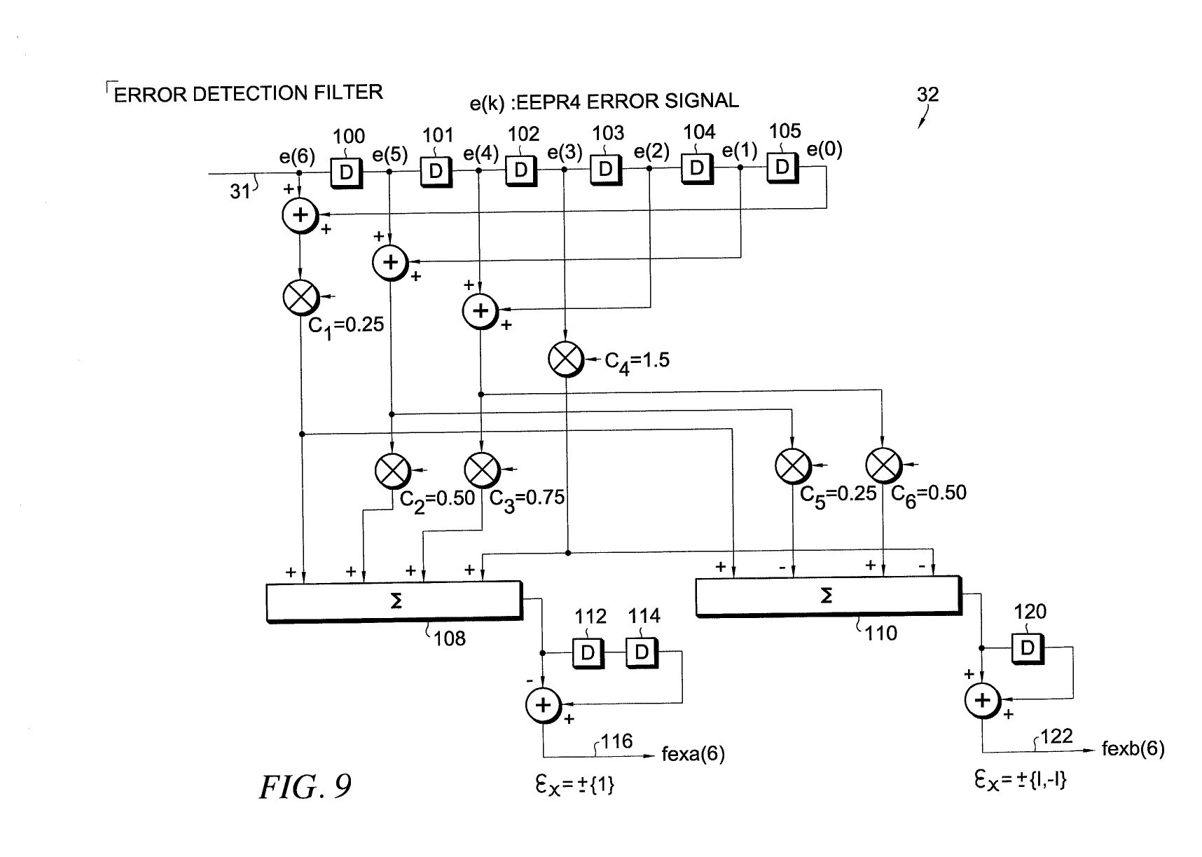

FIG. 8 shows the bit error rate performance comparisons by computer simulations with and without the post-processor for an EPR4ML channel. It can be seen that the bits error rate with the post-processor is significantly reduced then without the post-processor, for the same signal to noise ratio.

A noise whitening filter NW(D) and an error pattern matched filter MF(D) can be combined into a simple error pattern detection filter DF(D). The appropriate selection of b1, b2. . . and, m of the denominator of the equation for MW(D) above can simplify the equation.

An example of another application of this invention is done for a Trellis 8/9-code EEPR4ML channel. This code was proposed by W. Bliss, “An 8/9 Rate Time-Varying Trellis Code for High Density Magnetic Recording”, Intermag 97. A similar code was proposed by P. H. Siegel et al in May 14, 1997 as “Rate 8/9 Trellis Code for E2PR4”. This channel is better performance than 16/17 code EPR4 channel for AWGN.

The three dominant error patterns of the Trellis 8/9 code EEPR4ML channel are shown in Table 6.

TABLE 6

| Error pattern | Du = 2(SNR = 19dB) | Du = 3(SNR = 21.5dB) |
|---|---|---|
| Ex = ±{1} | 90.5% | 30.3% |
| Ex = ±{1-1} | 7.5% | 54.9% |
| Ex = ±{1001} | 1.1% | 11.6% |

The structure of the noise-whitening filter of the three dominant error pattern is as follows.

For ex=±{1}: NW1(D)=(1+a1*D+a2*D²+3*D⁵)/(1+D).

For ex=±{1-1}: NW2(D)=(1+a1*D+a2*D²+a3*D³)/(1+2*D+D²)

The selection of this structure simplifies the dominant error pattern detection filters.

The transfer function of ex=±t{1} is

DF1(D)={c1*(1+D⁶)+c2*(D+D⁵)+c3*(D²+D⁴)=c4*D³}*(1−D²).

The transfer function of ex=±{1-1} is

DF2(D)=(c5*(1+D⁶)+c6*(D+D⁵)+c7*(D²+D⁴)+c8*D⁸)*(1+D).

The transfer function of ex=±{1001} is

DF3(D)={c9*(1+D⁶)+c10*(D+D⁵)+c11*(D²+D⁴)+c12*D³}*(1−D)*(1−D+D²).

For simplicity, the DF3(D) filter can be removed, at the cost of a small degradation of the high user density performance (0.3dB loss at Du=3, compared with three error pattern detection post-processor). FIG. 9 is the optimized error pattern detection filters 32 of Trellis 8/9 code EEPR4 channel. The EPR4 error signal detector 32 includes six delay blocks 100-105. The outputs from blocks 105-103 are added respectively to the signals on the input line 31 and the outputs from blocks 100-101. The signals on the input line 31 and outputs from blocks 100-102 are weighted, as shown, by weighting factors c1, c2, c3, and c4 to be summed in a summer 108. In addition, the outputs from blocks 100 and 101 are weighted by weighting factors c5 and c6. The signals weighted by c1 and c6 are summed in a second summer 110, and the signals weighted by c4 and c5 are subtracted in the summer 110, as shown.

The output from the summer 108 is subtracted from itself after being twice delayed by delay blocks 112 and 114, to produce an output function signal on line 116 to correct for the error event A, or ±{1}. Similarly, the output from the summer 110 is added to itself after a single delay added by block 120 to produce the error correction function on output line 122 represented by the error event pattern B, or ±{1-1}.

The performance improvement is about 0.5-0.7 dB in the Du=2.25-3.25 for AWGN.

In this case, the coefficients set of these filters is not changed over the above Du range.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

I claim:

1. A post-processing method for use in a sampled data read channel of a mass data storage device that has a Viterbi detector that receives actual sampled partial response target data from a said data medium of a mass data storage device and produces a recovered data output signal, comprising:
filtering an a recovered partial response target signal derived from said recovered data output signal and said sampled partial response target data to produce a filtered output signal;
providing a threshold circuit to provide a threshold against which said filtered output signal is compared;
generating an error event pattern indicating signal when a predetermined error event pattern occurs in said recovered data output signal;
and modifying the recovered data output signal when said filtered output signal exceeds the threshold of said threshold circuit and said error event indicating signal is generated.

2. The method of claim 1 wherein said Viterbi detector is an EPR4 Viterbi detector.

3. The method of claim 1 wherein said Viterbi detector is an EEPR4 Viterbi detector.

4. The method of claim 1 wherein said error event pattern is ex=±{1}.

5. The method of claim 1 wherein said error event pattern is ex=±{1-11}.

6. The method of claim 1 wherein said error event pattern is ex=±{1-1}.

7. The method of claim 1 wherein said filtering is accomplished by applying said output to an FIR filter.

8. The method of claim 1 further comprising whitening the recovered data output signal, prior to said filtering, with a whitening filter.

9. A sampled data detection technique for use in a mass data storage device, comprising:
equalizing and sampling a read back signal from a transducer head of said mass data storage device to a partial response level of at least EPR4 to produce an actual sampled partial response target signal;
detecting said actual sampled partial response target signal in a Viterbi detector having a partial response detection level of at least EPR4 to produce a recovered data output signal;
delaying said actual sampled partial response target signal for a time substantially equal to a time required by said Viterbi detector to generate said recovered data output signal from said actual sampled partial response target signal to produce a delayed actual sampled partial response target signal;
converting said recovered data output signal to a partial response level of said actual sampled data output signal to produce a converted recovered partial response target signal;
subtracting said converted recovered partial response target signal from said delayed actual sampled partial response target signal to produce an error signal;
determining the occurrence of a predetermined error event pattern in said recovered data output signal to produce an error event pattern indicating signal;
producing, from said error signal, a detection signal having a magnitude based upon the occurrence of an error event;
comparing said detection signal to a predetermined threshold level, and generating an error correction control signal if said data detection signal is larger than said predetermined threshold level, and said error event pattern indicating signal indicates an occurrence of an error pattern; and
correcting said recovered data output signal to correspond to said predetermined data pattern if said error correction control signal has been generated.

10. The method of claim 9 wherein said equalizing comprises equalizing said read back signal to a partial response level of EPR4, and said detecting comprises detecting said actual sampled partial response target signal in a Viterbi detector having a partial response detection level of EPR4.

11. The method of claim 9 wherein said equalizing comprises equalizing said read back signal to a partial response level of EEPR4, and said detecting comprises detecting said actual sampled partial response target signal in a Viterbi detector having a partial response detection level of EEPR4.

12. The method of claim 9 wherein said producing a detection signal comprises filtering said error signal with an FIR filter.

13. The method of claim 9 further comprising whitening said error signal prior to said producing said detection signal.

14. The method of claim 9 wherein said determining the occurrence of a predetermined error event pattern in said recovered data output signal comprises determining the occurrence of ex=±{1} in said recovered data output signal.

15. The method of claim 9 wherein said determining the occurrence of a predetermined error event pattern in said recovered data output signal comprises determining the occurrence of ex=±{1-11} in said recovered data output signal.

16. The method of claim 9 wherein said determining the occurrence of a predetermined error event pattern in said recovered data output signal comprises determining the occurrence of ex=±{1-1} in said recovered data output signal.

17. The method of claim 9 wherein said determining the occurrence of a predetermined error event pattern in said recovered data output signal comprises determining a data sequence having a high likelihood of occurrence.

18. A post-processor circuit for use in a sampled data read channel of a mass data storage device, comprising:
a Viterbi detector that receives an actual sampled partial response target signal from a storage medium of said mass data storage device to produce a recovered data output signal;
an error pattern detector to generate an error pattern event indicating signal if a predetermined error event pattern occurs in said sampled partial response target signal;
a circuit for generating an error signal based upon a difference between said recovered data output signal and a delayed said actual sampled partial response target signal;
a threshold circuit to generate an error correction control signal if a magnitude of said error signal exceeds a predetermined threshold;
and an error correction circuit to modify the recovered data output signal when said error correction control signal and said error event pattern indicating occurrence signal are generated.

19. The circuit of claim 18 further comprising a whitening filter connected to receive said error signal to produce an input signal to said threshold circuit.

20. The circuit of claim 19 wherein said whitening filter has a transfer function, NW(D), that is equal to
(1+a1*D+a2*D²+ . . . +an*Dⁿ)/(1+b1*D+b2*D²+ . . . +bm*D^{m}),
in which a1, a2, . . . an, and b1, b2, . . . bm are coefficients related to a density in which data is recorded in said mass data storage device.

21. The circuit of claim 19 wherein said whitening filter has a transfer function, NW(D), that is equal to
(1+a1*D+a2*D²+a3*D³)/(1+D),
in which a1, a2, and a3 are coefficients related to a density in which data is recorded in said mass data storage device.

22. The circuit of claim 18 wherein said predetermined error pattern event is ex=±{1}.

23. The circuit of claim 18 wherein said predetermined error pattern event is ex=±{1-11}.

24. The circuit of claim 18 wherein said predetermined error pattern event is ex=±{1-1}.

25. The circuit of claim 18 wherein said circuit for generating an error signal is an FIR filter

26. The circuit of claim 18 wherein said circuit for generating an error signal is an error pattern matched filter.

27. The circuit of claim 18 wherein said circuit for generating an error signal comprises a whitening noise generator and an FIR filter connected to receive an output of said whitening noise generator.

28. The circuit of claim 18 wherein said Viterbi detector has a partial response level of at least EPR4.

29. The circuit of claim 18 wherein said Viterbi detector has a partial response level of at least EEPR4.
